(19) United States
(12) Patent Application Publication
(10) Pub. No.: US 2026/0287778 A1
(43) Pub. Date: Sep. 24, 2026

(54) MOVING OBJECT OF CONTACTLESS POWER TRANSMISSION SYSTEM, FOREIGN OBJECT DETECTION METHOD, AND STORAGE MEDIUM

(71) Applicant: HONDA MOTOR CO., LTD., Tokyo (JP)

(72) Inventors: Kosuke KAJITA, Tokyo (JP); Takahide SAGAE, Tokyo (JP); Ryotaro KAMIYA, Tokyo (JP)

(73) Assignee: HONDA MOTOR CO., LTD., Tokyo (JP)

(21) Appl. No.: 19/567,323

(22) Filed: Mar. 16, 2026

(30) Foreign Application Priority Data
Mar. 19, 2025 (JP) 2025-044454

(51) Int. Cl. G01V 3/02; B60L 53/124; G01R 19/165; H02J 50/10; H02J 50/60

(52) U.S. Cl. CPC G01V 3/02; B60L 53/124; G01R 19/16576; H02J 50/10; H02J 50/60; B60L 2210/40

(57) ABSTRACT

A moving object includes: a battery; a first unit mounted on the moving object and electrically connected to the battery; a switch provided between the battery and the first unit; and a control device including a processor that controls the first unit and the switch. The first unit includes: a first coil that receives or transmits power in a contactless manner from or to a second coil provided in a second unit provided outside the moving object; a conversion device that is connected between the first coil and the battery; and a capacitor provided between the conversion device and the battery, and the processor operates the conversion device in a disconnected state in which the battery and the first unit are disconnected by the switch, and executes foreign object detection of determining whether a metal foreign object is present between the first unit and the second unit.

### CROSS-REFERENCE TO RELATED APPLICATIONS

This application is based on and claims priority under 35 USC 119 from Japanese Patent Application No. 2025-044454 filed on Mar. 19, 2025, the contents of which are incorporated herein by reference.

### TECHNICAL FIELD

The present disclosure relates to a moving object of a contactless power transmission system that performs contactless power transmission between a moving-object-side unit and a ground-side unit, a foreign object detection method, and a storage medium.

### BACKGROUND

In recent years, in order to allow more people to access affordable, reliable, sustainable, and advanced energy, researches and developments have been conducted on charging and power supply in a mobility mounted with a secondary battery that contributes to an increase in energy efficiency. For example, Japanese Patent Publication No. 5940784 (hereinafter, referred to as Patent Literature 1) discloses a moving object contactless power supply device including a power transmission coil provided on a ground side and a power reception coil provided on a moving object side and facing the power transmission coil via a gap, and power is supplied from the power transmission coil to the power reception coil by electromagnetic induction.

The moving object contactless power supply device disclosed in Patent Literature 1 supplies foreign object detection power to the power transmission coil in a state in which no metal foreign object is present on the power transmission coil to obtain a standard value of a power supply loss, and detects presence or absence of a metal foreign object on the power transmission coil based on a difference between a measured value and the standard value of the power supply loss obtained by supplying the foreign object detection power to the power transmission coil.

In the technique disclosed in Patent Literature 1, it is required to establish communication between a vehicle side and the ground side in order to detect the foreign object.

In such a technique, since the foreign object cannot be detected when communication fails, there is a demand for a technique that does not require communication between the vehicle side and the ground side, specifically, a technique that enables a device on the vehicle side to accurately detect the foreign object.

The present disclosure provides a moving object of a contactless power transmission system, a foreign object detection method, and a storage medium that can accurately detect a foreign object by a device of the moving object without using a ground-side unit.

### SUMMARY

A first aspect of the present disclosure relates to a moving object of a contactless power transmission system. The contactless power transmission system performs contactless power transmission between a moving-object-side unit mounted on the moving object and a ground-side unit provided outside the moving object. The moving object includes: a battery; the moving-object-side unit electrically connected to the battery; a switch provided between the battery and the moving-object-side unit and switchable between electrical connection and disconnection between the battery and the moving-object-side unit; and a control device including a processor that controls the moving-object-side unit and the switch. The moving-object-side unit includes: a moving-object-side coil that receives or transmits power in a contactless manner from or to a ground-side coil provided in the ground-side unit; a power conversion device that is connected between the moving-object-side coil and the battery and performs power conversion between DC power and AC power; and a capacitor provided between the power conversion device and the battery, and the processor operates the power conversion device in a disconnected state in which the battery and the moving-object-side unit are disconnected by the switch, and executes foreign object detection of determining whether a metal foreign object is present between the moving-object-side unit and the ground-side unit.

A second aspect of the present disclosure relates to a foreign object detection method of a contactless power transmission system. The contactless power transmission system performs contactless power transmission between a moving-object-side unit mounted on a moving object and a ground-side unit provided outside the moving object, the moving object includes a battery and the moving-object-side unit electrically connected to the battery, the moving-object-side unit includes a moving-object-side coil that receives or transmits power in a contactless manner from or to a ground-side coil provided in the ground-side unit, a power conversion device that is connected between the moving-object-side coil and the battery and performs power conversion between DC power and AC power, and a capacitor provided between the power conversion device and the battery, and the foreign object detection method performed by a processor includes: disconnecting electrical connection between the battery and the moving-object-side unit before the contactless power transmission is performed; and operating the power conversion device in a disconnected state in which the battery and the moving-object-side unit are disconnected, and determining whether a metal foreign object is present between the moving-object-side unit and the ground-side unit.

A third aspect of the present disclosure relates to a non-transitory computer-readable storage medium storing a foreign object detection program of a contactless power transmission system for causing a computer to execute a process. The contactless power transmission system performs contactless power transmission between a moving-object-side unit mounted on a moving object and a ground-side unit provided outside the moving object, the moving object includes a battery and the moving-object-side unit electrically connected to the battery, the moving-object-side unit includes a moving-object-side coil that receives or transmits power in a contactless manner from or to a ground-side coil provided in the ground-side unit, a power conversion device that is connected between the moving-object-side coil and the battery and performs power conversion between DC power and AC power, and a capacitor provided between the power conversion device and the battery, and the process includes: disconnecting electrical connection between the battery and the moving-object-side unit before the contactless power transmission is performed; and operating the power conversion device in a disconnected state in which the battery and the moving-object-side unit are disconnected, and determining whether a metal foreign object is present between the moving-object-side unit and the ground-side unit.

According to the present disclosure, it is possible to accurately detect a foreign object by a device of a moving object without using a ground-side unit.

### BRIEF DESCRIPTION OF DRAWINGS

Exemplary embodiments of the present invention will be described in detail based on the following figures, wherein:

FIG. 1 is a schematic configuration diagram of a contactless power transmission system according to an embodiment of the present disclosure;

FIG. 2 is a functional block diagram of the contactless power transmission system;

FIG. 3 is a circuit diagram including a battery, a vehicle-side unit, and a contactor mounted on a vehicle;

FIG. 4 is a schematic side view of a ground-side unit and the vehicle-side unit;

FIG. 5 is a flowchart showing an example of processing executed by a processor;

FIG. 6 is a continuation of the flowchart in FIG. 5, and specifically shows a flowchart of foreign object detection; and

FIG. 7 is a flowchart of a modification of the foreign object detection.

### DESCRIPTION OF EMBODIMENTS

Hereinafter, one embodiment of a moving object of a contactless power transmission system, a foreign object detection method, and a storage medium of the present disclosure will be described with reference to the accompanying drawings. The drawings are viewed in directions of reference signs. The drawings are viewed in directions of reference signs. In the present specification and the like, in order to simplify and clarify the description, in the drawings, a front side of a vehicle is shown as Fr, a rear side is shown as Rr, a left side is shown as L, a right side is shown as R, an upper side is shown as U, and a lower side is shown as D.

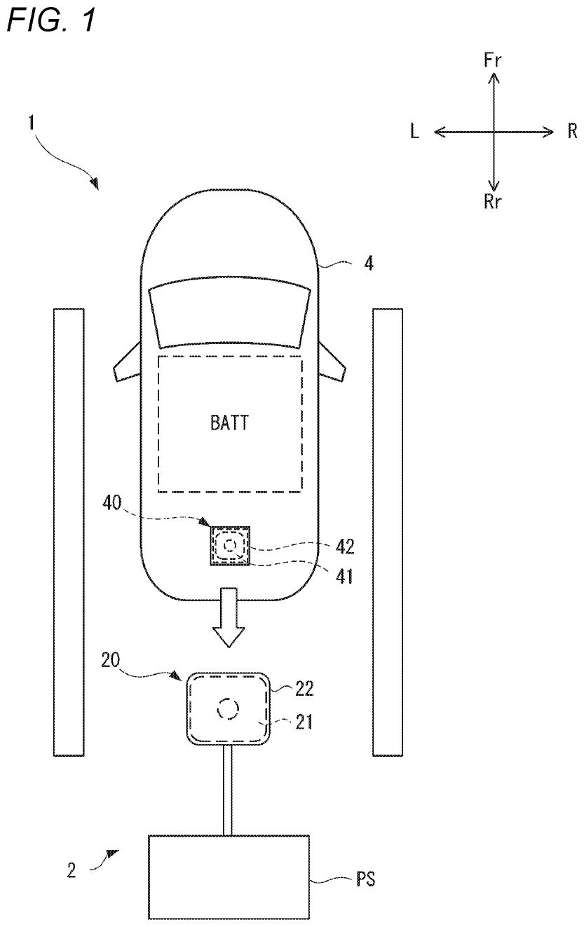

FIG. 1 is a schematic configuration diagram of a contactless power transmission system 1 according to an embodiment of the present disclosure. The contactless power transmission system 1 includes ground-side equipment 2 where a ground-side unit 20 is provided, and a vehicle 4 where a vehicle-side unit 40 is mounted. In the contactless power transmission system 1, contactless power transmission for transmitting power in a contactless manner is performed between the ground-side unit 20 and the vehicle-side unit 40, using magnetic coupling between coils of, for example, a magnetic resonance method or an electromagnetic induction method.

The contactless power transmission includes power transmission from the ground-side unit 20 to the vehicle-side unit 40 and power transmission from the vehicle-side unit 40 to the ground-side unit 20. The power transmission from the ground-side unit 20 to the vehicle-side unit 40 corresponds to charging of a battery BATT mounted on the vehicle 4, and the power transmission from the vehicle-side unit 40 to the ground-side unit 20 corresponds to power supply from the battery BATT to the outside of the vehicle 4.

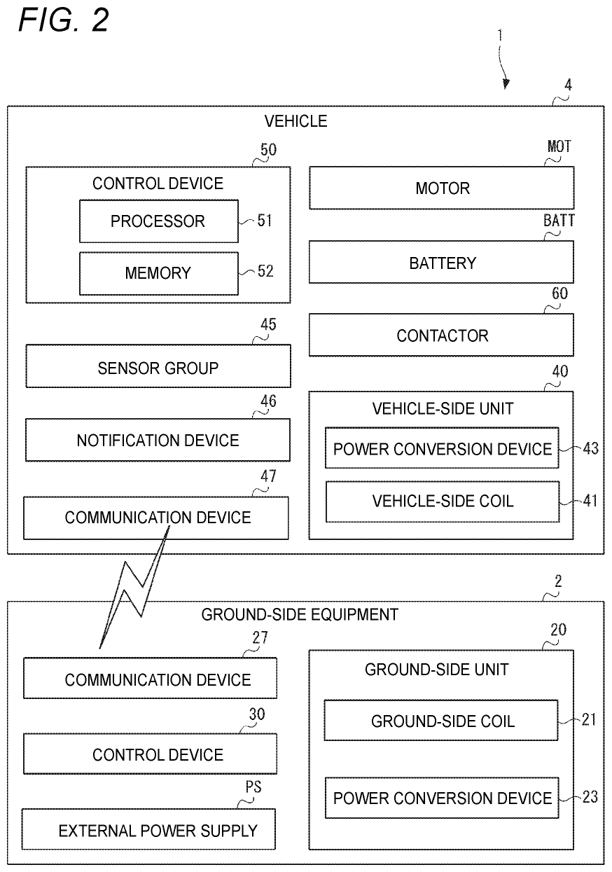

The ground-side equipment 2 is provided in a predetermined parking space or the like. As shown in FIG. 2, the ground-side equipment 2 includes the ground-side unit 20, a communication device 27 that can communicate with the vehicle 4, a control device 30 that controls the ground-side unit 20, and a power supply device PS connected to an external power system such as a commercial power supply.

The ground-side unit 20 includes a ground-side coil 21 provided on the ground, a resin pad 22 covering the ground-side coil 21, and a power conversion device 23 that converts AC power supplied from the power supply device PS into high-frequency AC power and supplies the converted high-frequency AC power to the ground-side coil 21. A shape of the ground-side coil 21 is, for example, circular in a plan view, but is not limited thereto and may be elliptical, square, or rectangular.

The communication device 27 is a communication interface that performs wireless communication with a communication device 47 of the vehicle 4. For the wireless communication, for example, Wi-Fi (registered trademark) or Bluetooth (registered trademark) can be used.

The control device 30 includes, for example, a processor and a memory, and performs overall control of the ground-side equipment 2. The processor is configured as one or a plurality of electric circuits in which circuit elements such as semiconductor elements are combined. The memory functions as a storage unit and includes a random access memory (RAM) required for operating the processor, a read only memory (ROM) that stores programs and data, and the like.

The vehicle 4 is an electric vehicle whose battery BATT can be charged by power supplied from the outside, and is, for example, a battery electric automobile or a plug-in hybrid vehicle. When the battery BATT is charged, the vehicle-side unit 40 receives power transmitted from the ground-side unit 20 in a contactless manner and stores the received power in the battery BATT. The battery BATT is, for example, a lithium ion battery or a nickel-metal hydride battery. The vehicle 4 can travel by driving a motor MOT, which is a drive source, using the power stored in the battery BATT. The vehicle 4 may be allowed to supply the power stored in the battery BATT to the outside. Specifically, the vehicle 4 may transmit power from the vehicle-side unit 40 to the ground-side unit 20 in a contactless manner.

The vehicle 4 has an autonomous parking function for autonomously moving to and parking in a predetermined parking space. The autonomous parking function operates, for example, in response to a request from an occupant. When the autonomous parking function is operated in the vicinity of the parking space where the ground-side equipment 2 is provided, the vehicle 4 autonomously moves toward a target parking position. A parking position where power transmission efficiency is maximized is a position where centers of the ground-side unit 20 and the vehicle-side unit 40 coincide with each other, and the vehicle 4 basically sets this position where the power transmission efficiency is maximized as the target parking position and autonomously moves.

As shown in FIGS. 1 and 2, the vehicle 4 includes the battery BATT, the motor MOT serving as the drive source, the vehicle-side unit 40 electrically connected to the battery BATT, a contactor 60 provided between the battery BATT and the vehicle-side unit 40, a sensor group 45, a notification device 46, the communication device 47, and a control device 50.

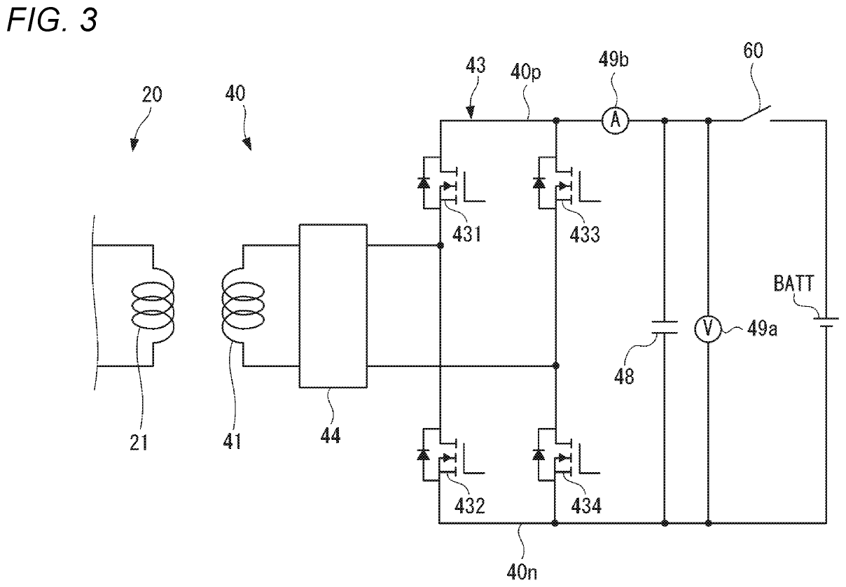

As shown in FIG. 3, the vehicle-side unit 40 includes a vehicle-side coil 41 that performs power reception or power transmission in a contactless manner with the ground-side coil 21, a resin pad 42 (see FIG. 1) that covers the vehicle-side coil 41, a power conversion device 43 that is connected between the vehicle-side coil 41 and the battery BATT and performs power conversion between DC power and AC power, a resonance circuit 44 connected between the vehicle-side coil 41 and the power conversion device 43, and a smoothing capacitor 48 provided between the power conversion device 43 and the battery BATT. A shape of the vehicle-side coil 41 is, for example, circular in a plan view, but is not limited thereto and may be elliptical, square, or rectangular.

The power conversion device 43 includes, for example, an inverter that forms a bridge circuit by four switching elements 431 to 434 connected in a two-phase bridge connection. The plurality of switching elements 431 to 434 include upper arm elements (switching elements 431 and 433) and lower arm elements (switching elements 432 and 434) that form pairs in each phase. Each of the switching elements 431 to 434 is a power switching element such as an insulated gate bipolar transistor (IGBT) or a field effect transistor (FET), and is a metal oxide semiconductor field effect transistor (MOSFET) in the shown example. A drain current flowing between a drain terminal and a source terminal is controlled by a gate voltage applied between a gate terminal and the source terminal. In each of the switching elements 431 to 434, a rectifying element is formed between the source terminal and the drain terminal, and in the shown example, the rectifying element is a parasitic diode of the MOSFET.

The drain terminal of each of the switching elements 431 and 433, which are the upper arm elements, is connected to a positive-electrode-side power line 40p, and the source terminal of each of the switching elements 432 and 434, which are the lower arm elements, is connected to a negative-electrode-side power line 40n. The source terminal of each of the switching elements 431 and 433 and the drain terminal of each of the switching elements 432 and 434 are connected to the resonance circuit 44.

The resonance circuit 44 includes, for example, a resonance capacitor connected in series to the vehicle-side coil 41. When power is transmitted from the ground-side unit 20 to the vehicle-side unit 40, the vehicle-side coil 41 and the resonance circuit 44 constitute a power receiving unit that receives the power transmitted from the ground-side unit 20 in a contactless manner. When power is transmitted from the vehicle-side unit 40 to the ground-side unit 20, the vehicle-side coil 41 and the resonance circuit 44 constitute a power transmission unit that transmits the power to the ground-side unit 20 in a contactless manner.

The smoothing capacitor 48 is connected to the positive-electrode-side power line 40p and the negative-electrode-side power line 40n. The smoothing capacitor 48 smooths a voltage fluctuation that occurs along with a switching operation between ON (connection) and OFF (disconnection) of each of the switching elements 431 to 434. The smoothing capacitor 48 is an example of a capacitor in the present disclosure.

The vehicle-side unit 40 further includes a voltage sensor 49a that detects a voltage of the smoothing capacitor 48, and a current sensor 49b that is provided between the power conversion device 43 and the smoothing capacitor 48 to detect a current. In the present embodiment, the vehicle-side unit 40 may not include the current sensor 49b.

The contactor 60 can switch electrical connection and disconnection between the battery BATT and the vehicle-side unit 40 by ON/OFF control. The contactor 60 is disposed on a positive electrode side of the battery BATT. The contactor 60 is basically OFF (in an open state) except when contactless power transmission is performed. The contactor 60 is an example of a switch in the present disclosure.

Referring back to FIG. 2, the sensor group 45 acquires various detection values used for controlling the vehicle 4. The sensor group 45 includes, for example, a camera (image sensor) and a sonar for acquiring surrounding information of the vehicle 4. The sensor group 45 also includes, for example, a wheel sensor, a positioning sensor, and a steering angle sensor for acquiring state information of the vehicle 4. The sensor group 45 may also include other sensors, for example, radar and light detection and ranging (LiDAR) for acquiring the surrounding information of the vehicle 4.

The notification device 46 is an output destination of notification processing by the control device 50, and notifies the occupant of the vehicle 4 of predetermined information. The notification device 46 is, for example, a display (also including a head-up display) or a speaker provided in the vehicle 4, and notifies the occupant of predetermined information by video or audio. The notification device 46 may also be a user terminal such as a smartphone or a tablet terminal owned by the occupant.

The communication device 47 is a communication interface that performs wireless communication with the communication device 27 of the ground-side equipment 2. For the wireless communication, for example, Wi-Fi (registered trademark) or Bluetooth (registered trademark) can be used. The communication device 47 can also perform wireless communication via a network using a mobile communication network such as “4G” or “5G”.

The control device 50 is, for example, an electronic control unit (ECU) including a processor 51 and a memory 52. The processor 51 is configured as one or a plurality of electric circuits in which circuit elements such as semiconductor elements are combined. The memory 52 functions as a storage unit and includes a RAM required for operating the processor 51, a ROM that stores programs and data, and the like.

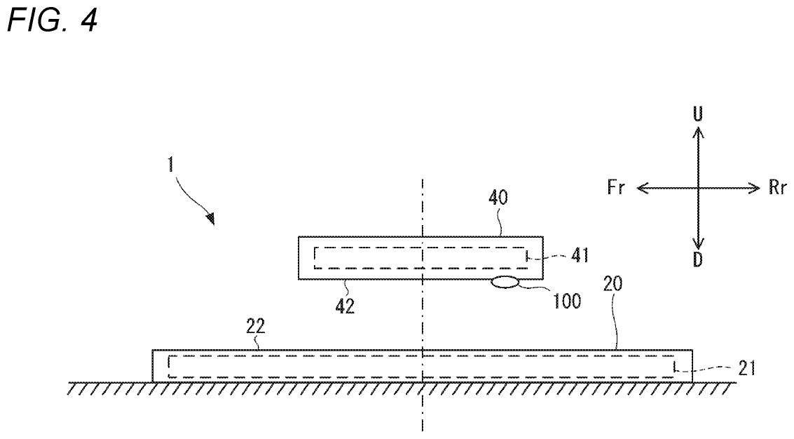

Next, a method for detecting a metal foreign object 100 in the contactless power transmission system 1 will be described with reference to FIGS. 4 to 6. When the contactless power transmission is performed in a state in which the foreign object 100 is present between the ground-side unit 20 and the vehicle-side unit 40, an eddy current is generated in the foreign object 100 to generate heat, which may cause a high temperature. In addition, heat generation of the foreign object 100 may increase a power transmission loss. In order to ensure safety and reduce the power transmission loss, it is required to remove the foreign object 100 before performing the contactless power transmission.

The ground-side unit 20 may be provided with a foreign object detector. The foreign object detector includes, for example, a coil array in which a plurality of foreign object detection coils are dispersedly distributed along a substantially flat plane and partially or entirely embedded in the pad 22. The foreign object detector detects a metal foreign object based on a manner of change in an oscillation waveform signal supplied from an oscillator to each of the foreign object detection coils.

A detection range of the foreign object detector constituted by such a coil array is about several tens of mm from a surface of the ground-side unit 20, and when the foreign object 100 is located away from the surface of the ground-side unit 20, it is difficult to detect the foreign object 100 by the foreign object detector of the ground-side unit 20. For example, when the foreign object 100 adheres to the pad 42 of the vehicle-side unit 40 as shown in FIG. 4, it is difficult for the foreign object detector of the ground-side unit 20 to detect the foreign object 100.

In the case of a configuration in which the foreign object 100 is detected only by the foreign object detector of the ground-side unit 20, for example, when a communication failure occurs between the ground-side equipment 2 and the vehicle 4 due to a malfunction of the ground-side equipment 2, the vehicle 4 cannot detect the foreign object 100.

Therefore, the contactless power transmission system 1 of the present embodiment is configured to detect the foreign object 100 by a vehicle-side device without using the ground-side unit 20. Accordingly, the vehicle 4 can detect the foreign object 100 even when the foreign object 100 is located away from the ground-side unit 20. In addition, even when a communication failure occurs between the ground-side equipment 2 and the vehicle 4, the vehicle 4 can detect the foreign object 100.

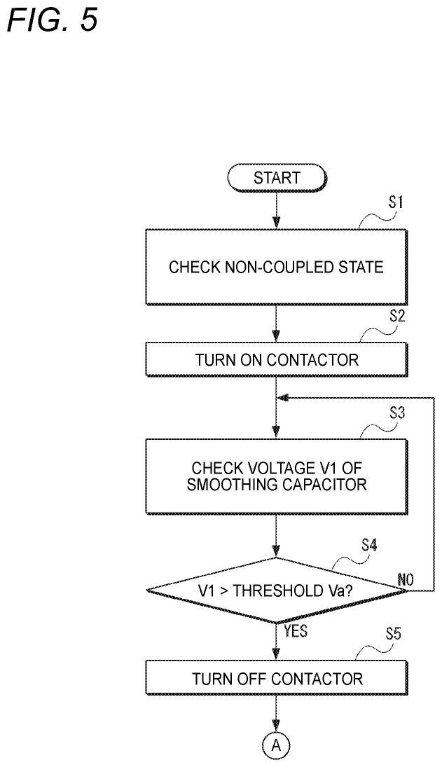

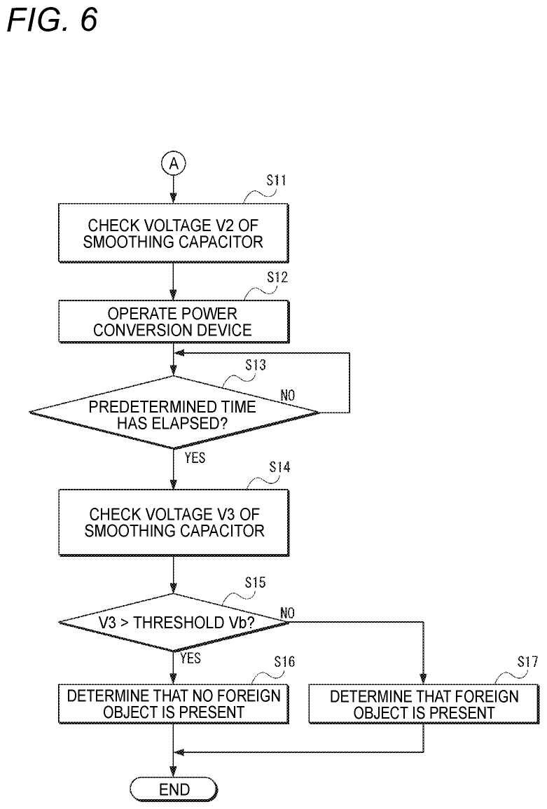

FIGS. 5 and 6 are flowcharts showing an example of processing executed by the processor 51. Among the processing shown in the flowchart, various types of processing shown in FIG. 6 correspond to foreign object detection. The processing shown in the flowchart is executed, for example, after parking completion of the vehicle 4 into the parking space and before the vehicle-side unit 40 and the ground-side unit 20 are coupled.

First, the processor 51 checks that the vehicle-side unit 40 and the ground-side unit 20 are in a non-coupled state (step S1). Since the foreign object detection is preferably executed before the vehicle-side unit 40 and the ground-side unit 20 are magnetically coupled so as not to be influenced by the ground-side unit 20, the processor 51 first checks that the state is the non-coupled state.

The processor 51 turns on the contactor 60 (into a closed state) to electrically connect the battery BATT and the vehicle-side unit 40 (step S2). At this time, the processor 51 does not operate the power conversion device 43. By turning on the contactor 60, the battery BATT and the smoothing capacitor 48 are electrically connected, and electric charge is accumulated in the smoothing capacitor 48 for precharging.

The processor 51 checks the voltage of the smoothing capacitor 48 (step S3). The voltage of the smoothing capacitor 48 is a detection value detected by the voltage sensor 49a. The voltage checked in step S3 is V1.

The processor 51 compares the voltage V1 of the smoothing capacitor 48 with a threshold Va (step S4). When the voltage V1 is equal to or less than the threshold Va (step S4: NO), the processor 51 returns to step S3 and monitors until the voltage V1 becomes greater than the threshold Va.

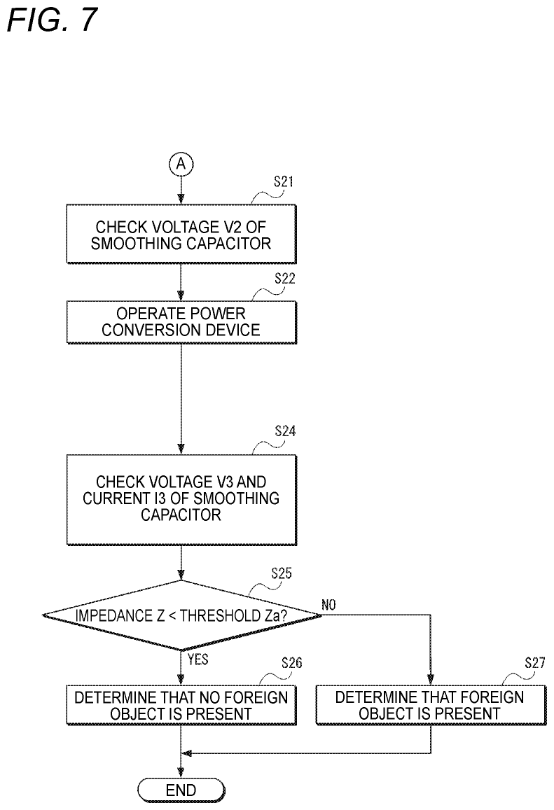

When the voltage V1 is greater than the threshold Va (step S4: YES), the processor 51 turns off the contactor 60 (into an open state) and electrically disconnects the battery BATT and the vehicle-side unit 40 (step S5). In the disconnected state in which the battery BATT and the vehicle-side unit 40 are disconnected, the processor 51 executes the foreign object detection shown in FIG. 7.

The processor 51 checks the voltage of the smoothing capacitor 48 (step S11). The voltage of the smoothing capacitor 48 is the detection value detected by the voltage sensor 49a. The voltage checked in step S11 is V2.

The processor 51 operates the power conversion device 43 (step S12). Specifically, the processor 51 controls ON/OFF switching of each of the switching elements 431 to 434. The electric charge stored in the smoothing capacitor 48 is supplied to the vehicle-side coil 41 via the power conversion device 43 and the resonance circuit 44, and a magnetic field is generated around the vehicle-side coil 41.

The processor 51 determines whether a predetermined time has elapsed since the power conversion device 43 is operated (step S13). The processor 51 continues the operation of the power conversion device 43 until the predetermined time elapses.

When the predetermined time has elapsed (step S13: YES), the processor 51 checks the voltage of the smoothing capacitor 48 (step S14). The voltage of the smoothing capacitor 48 is the detection value detected by the voltage sensor 49a. The voltage checked in step S14 is V3.

The processor 51 compares the voltage V3 of the smoothing capacitor 48 with a threshold Vb (step S15). The threshold Vb is, for example, a value calculated by collecting data of the voltage V3 in cases where the foreign object 100 is present and absent, and is stored in the memory 52 in advance.

When the foreign object 100 is present, the eddy current is generated in the foreign object 100 due to the magnetic field generated around the vehicle-side coil 41, a loss in the vehicle-side coil 41 increases, and thus a change amount (decrease amount) of the voltage of the smoothing capacitor 48 in the predetermined time is greater than that in a case where the foreign object 100 is not present.

When the voltage V3 is greater than the threshold Vb (step S15: YES), since the change amount of the voltage of the smoothing capacitor 48 is not large, the processor 51 determines that the foreign object 100 is not present (step S16). After determining that the foreign object 100 is not present, the processor 51 starts the contactless power transmission.

On the other hand, when the voltage V3 is equal to or less than the threshold Vb (step S15: NO), since the change amount of the voltage of the smoothing capacitor 48 is large, the processor 51 determines that the foreign object 100 is present (step S17). When it is determined that the foreign object 100 is present, the processor 51 notifies the occupant of the presence of the foreign object 100 via the notification device 46, for example. In this way, the foreign object 100 can be detected only by the detection value from the voltage sensor 49a, and the foreign object 100 can be detected without using a large number of components for foreign object detection.

In step S15, the processor 51 may determine that the foreign object 100 is present when the change amount of the voltage of the smoothing capacitor 48 after the predetermined time elapses, specifically, a difference between the voltage V2 and the voltage V3 is equal to or greater than a predetermined value.

As described above, according to the contactless power transmission system 1 of the present embodiment, since the foreign object detection is executed using the vehicle-side coil 41 and the processor 51, which are devices of the vehicle 4, the vehicle 4 can detect the foreign object 100 even when the foreign object 100 is located away from the ground-side unit 20 and cannot be detected by the foreign object detector of the ground-side unit 20. In addition, the vehicle 4 can detect the foreign object 100 without communicating with the ground-side equipment 2.

The contactor 60 is provided between the battery BATT and the vehicle-side unit 40, and the processor 51 operates the power conversion device 43, in a state in which the contactor 60 is OFF and the battery BATT and the vehicle-side unit 40 are disconnected, to execute the foreign object detection. Accordingly, an influence of the battery BATT can be eliminated in the foreign object detection. Specifically, when the change amount of the voltage of the smoothing capacitor 48 is large, there is a high probability that a factor thereof is not due to an influence of a voltage fluctuation of the battery BATT (a voltage of the battery BATT fluctuates depending on a remaining capacity) but due to the presence of the foreign object 100. That is, the processor 51 can accurately detect the foreign object 100.

Further, since the processor 51 executes the foreign object detection before the vehicle-side unit 40 and the ground-side unit 20 are coupled, when the change amount of the voltage of the smoothing capacitor 48 is large, there is a higher probability that it can be estimated that a factor thereof is not due to the ground-side unit 20 but due to the presence of the foreign object 100. That is, the processor 51 can more accurately detect the foreign object 100. Further, since power is not transmitted from the vehicle-side unit 40 to the ground-side unit 20 in the foreign object detection, the processor 51 can detect the foreign object 100 with low power.

### Modification

FIG. 7 is a flowchart showing a modification of the foreign object detection executed by the processor 51. The foreign object detection in this modification is also executed through the flowchart shown in FIG. 5, and is executed in the state in which the battery BATT and the vehicle-side unit 40 are electrically disconnected.

The processor 51 checks the voltage of the smoothing capacitor 48 (step S21). The voltage of the smoothing capacitor 48 is the detection value detected by the voltage sensor 49a. The voltage checked in step S21 is V2.

The processor 51 operates the power conversion device 43 (step S22). Specifically, the processor 51 controls ON/OFF switching of each of the switching elements 431 to 434. The electric charge stored in the smoothing capacitor 48 is supplied to the vehicle-side coil 41 via the power conversion device 43 and the resonance circuit 44, and a magnetic field is generated around the vehicle-side coil 41.

The processor 51 checks the voltage of the smoothing capacitor 48 and the current detected by the current sensor 49b (step S24). The voltage of the smoothing capacitor 48 is the detection value detected by the voltage sensor 49a, the voltage checked in step S24 is V3, and the current is I3.

The processor 51 calculates an impedance Z based on the voltage V3 and the current I3, and compares the impedance Z with a threshold Za (step S25). For example, the processor 51 can calculate the impedance Z by dividing the voltage V3 by the current I3 (that is, Z=V3/I3). The threshold Za is, for example, a value calculated by collecting data of the voltage V3 and the current I3 in cases where the foreign object 100 is present and absent, and is stored in the memory 52 in advance.

When the impedance Z is less than the threshold Za (step S25: YES), the processor 51 determines that the foreign object 100 is not present (step S26).

When the impedance Z is equal to or greater than the threshold Za (step S25: NO), it is estimated that a loss is large due to the presence of the foreign object 100, and the processor 51 determines that the foreign object 100 is present (step S27).

The foreign object detection in the modification can also obtain the same effect as the foreign object detection in the above-described embodiment. Further, in the foreign object detection of the modification, the processor 51 can determine the presence of the foreign object 100 without waiting for the elapse of the predetermined time after operating the power conversion device 43 in step S22, and thus can shorten a processing time. Thus, when the foreign object 100 is not present, the contactless power transmission can be started promptly after the vehicle 4 is parked.

The various types of processing in the flowcharts of the embodiment and the modification described above can be implemented by executing a program prepared in advance (that is, a foreign object detection program of the present disclosure) by a computer, specifically, the processor 51. The program is stored in a computer-readable storage medium and executed by being read from the storage medium. In addition, the program may be provided in a form stored in a non-transitory storage medium such as a flash memory, or may be provided via a network.

Although one embodiment of the present disclosure has been described above with reference to the accompanying drawings, it is needless to say that the present disclosure is not limited to the embodiment. It is apparent to those skilled in the art that various changes or modifications can be conceived within the scope described in the claims, and it is understood that the changes or modifications naturally fall within the technical scope of the present disclosure. In addition, the constituent elements in the above embodiment may be freely combined without departing from the gist of the disclosure.

For example, the moving object of the present disclosure is not limited to the vehicle 4 such as the above-described battery electric automobile or plug-in hybrid vehicle as long as the contactless power transmission with the ground-side unit 20 can be performed. The moving object may be, for example, a two-wheeled vehicle or a work vehicle (both of which are other examples of the vehicle 4), or may be an aerial vehicle.

The determination in step S15 described above is performed after the predetermined time elapses since the power conversion device 43 is operated, but the determination is not limited thereto. For example, the processor 51 may always check (accumulate data of) the voltage V3 of the smoothing capacitor 48 after operating the power conversion device 43. Then, when the voltage V3 of the smoothing capacitor 48 becomes equal to or less than the threshold Vb during the predetermined time, or when the change amount of the smoothing capacitor 48 becomes equal to or greater than the predetermined value during the predetermined time, the processor 51 may determine that the foreign object 100 is present before the predetermined time elapses.

In the present specification, at least the following matters are described. In the parentheses, the corresponding constituent elements and the like in the above embodiment are shown as an example, but the present disclosure is not limited thereto.

(1) A moving object (vehicle 4) of a contactless power transmission system (contactless power transmission system 1) that performs contactless power transmission between a moving-object-side unit (vehicle-side unit 40) mounted on the moving object and a ground-side unit (ground-side unit 20) provided outside the moving object, the moving object of the contactless power transmission system including:
a battery (battery BATT);
the moving-object-side unit electrically connected to the battery;
a switch (contactor 60) provided between the battery and the moving-object-side unit and switchable between electrical connection and disconnection between the battery and the moving-object-side unit; and
a control device (control device 50) including a processor (processor 51) that controls the moving-object-side unit and the switch, in which
the moving-object-side unit includes
   a moving-object-side coil that receives or transmits power in a contactless manner from or to a ground-side coil provided in the ground-side unit,
   a power conversion device (power conversion device 43) that is connected between the moving-object-side coil and the battery and performs power conversion between DC power and AC power, and
   a capacitor (smoothing capacitor 48) provided between the power conversion device and the battery, and
the processor operates the power conversion device in a disconnected state in which the battery and the moving-object-side unit are disconnected by the switch, and executes foreign object detection of determining whether a metal foreign object (foreign object 100) is present between the moving-object-side unit and the ground-side unit.

According to (1), the foreign object detection can be executed by the device of the moving object without depending on the ground-side unit. In addition, since the switch is provided between the battery and the moving-object-side unit, and the processor executes the foreign object detection in the state in which the battery and the moving-object-side unit are electrically disconnected, an influence of the battery can be eliminated in the foreign object detection, and the foreign object can be accurately detected.

(2) The moving object of the contactless power transmission system according to (1), in which
the processor executes the foreign object detection before the moving-object-side unit and the ground-side unit are coupled.

According to (2), it is possible to accurately detect the foreign object without being influenced by the ground-side unit. In addition, since power is not transmitted from the moving-object-side unit to the ground-side unit, the foreign object can be detected with low power.

(3) The moving object of the contactless power transmission system according to (1) or (2), in which
the moving-object-side unit further includes a voltage detection unit (voltage sensor 49a) that detects a voltage of the capacitor, and
the processor determines whether the foreign object is present based on a detection result from the voltage detection unit in the foreign object detection.

According to (3), the foreign object can be detected without using a large number of components for foreign object detection.

(4) The moving object of the contactless power transmission system according to (3), in which
in the foreign object detection, the processor determines that the foreign object is present when a voltage detected by the voltage detection unit during a predetermined time after the power conversion device is operated or after the predetermined time elapses is equal to or less than a threshold.

According to (4), the foreign object can be detected based on the voltage of the capacitor during the predetermined time or after the predetermined time elapses.

(5) The moving object of the contactless power transmission system according to (3), in which
in the foreign object detection, the processor determines that the foreign object is present when a voltage change amount detected by the voltage detection unit during a predetermined time after the power conversion device is operated or after the predetermined time elapses is equal to or greater than a predetermined value.

According to (5), the foreign object can be detected based on the change amount of the voltage of the capacitor during the predetermined time or after the predetermined time elapses.

(6) The moving object of the contactless power transmission system according to (3), in which
the moving-object-side unit further includes a current detection unit (current sensor 49b) that is provided between the power conversion device and the capacitor to detect a current, and
in the foreign object detection, the processor
   calculates an impedance based on detection results from the voltage detection unit and the current detection unit, and
   determines that the foreign object is present when the impedance is equal to or greater than a threshold.

According to (6), a foreign object detection time can be shortened.

(7) A foreign object detection method of a contactless power transmission system that performs contactless power transmission between a moving-object-side unit mounted on a moving object and a ground-side unit provided outside the moving object, in which
the moving object includes a battery and the moving-object-side unit electrically connected to the battery,
the moving-object-side unit includes a moving-object-side coil that receives or transmits power in a contactless manner from or to a ground-side coil provided in the ground-side unit, a power conversion device that is connected between the moving-object-side coil and the battery and performs power conversion between DC power and AC power, and a capacitor provided between the power conversion device and the battery, and
the foreign object detection method includes:
   causing a processor to execute processing of
      disconnecting electrical connection between the battery and the moving-object-side unit before the contactless power transmission is performed (step S5), and
      operating the power conversion device in a disconnected state in which the battery and the moving-object-side unit are disconnected (step S12, S22), and determining whether a metal foreign object is present between the moving-object-side unit and the ground-side unit (step S15, S25).

According to (7), the foreign object detection can be executed by the device of the moving object without depending on the ground-side unit. In addition, since the foreign object detection is executed in the state in which the battery and the moving-object-side unit are electrically disconnected, an influence of the battery can be eliminated in the foreign object detection, and the foreign object can be accurately detected.

(8) A foreign object detection program of a contactless power transmission system that performs contactless power transmission between a moving-object-side unit mounted on a moving object and a ground-side unit provided outside the moving object, in which
the moving object includes a battery and the moving-object-side unit electrically connected to the battery,
the moving-object-side unit includes a moving-object-side coil that receives or transmits power in a contactless manner from or to a ground-side coil provided in the ground-side unit, a power conversion device that is connected between the moving-object-side coil and the battery and performs power conversion between DC power and AC power, and a capacitor provided between the power conversion device and the battery, and
a computer (processor 51) is caused to execute processing of
   disconnecting electrical connection between the battery and the moving-object-side unit before the contactless power transmission is performed, and
   operating the power conversion device in a disconnected state in which the battery and the moving-object-side unit are disconnected, and determining whether a metal foreign object is present between the moving-object-side unit and the ground-side unit.

According to (8), the foreign object detection can be executed by the device of the moving object without depending on the ground-side unit. In addition, since the foreign object detection is executed in the state in which the battery and the moving-object-side unit are electrically disconnected, an influence of the battery can be eliminated in the foreign object detection, and the foreign object can be accurately detected.

1. A moving object of a contactless power transmission system, wherein
the contactless power transmission system performs contactless power transmission between a moving-object-side unit mounted on the moving object and a ground-side unit provided outside the moving object,
the moving object comprises:
a battery;
the moving-object-side unit electrically connected to the battery;
a switch provided between the battery and the moving-object-side unit and switchable between electrical connection and disconnection between the battery and the moving-object-side unit; and
a control device including a processor that controls the moving-object-side unit and the switch, wherein
the moving-object-side unit comprises:
a moving-object-side coil that receives or transmits power in a contactless manner from or to a ground-side coil provided in the ground-side unit;
a power conversion device that is connected between the moving-object-side coil and the battery and performs power conversion between DC power and AC power; and
a capacitor provided between the power conversion device and the battery, and
the processor operates the power conversion device in a disconnected state in which the battery and the moving-object-side unit are disconnected by the switch, and executes foreign object detection of determining whether a metal foreign object is present between the moving-object-side unit and the ground-side unit.

2. The moving object of the contactless power transmission system according to claim 1, wherein
the processor executes the foreign object detection before the moving-object-side unit and the ground-side unit are coupled.

3. The moving object of the contactless power transmission system according to claim 1, wherein
the moving-object-side unit further includes a voltage detection unit that detects a voltage of the capacitor, and
the processor determines whether the foreign object is present based on a detection result from the voltage detection unit in the foreign object detection.

4. The moving object of the contactless power transmission system according to claim 3, wherein
in the foreign object detection, the processor determines that the foreign object is present when a voltage detected by the voltage detection unit during a predetermined time after the power conversion device is operated or after the predetermined time elapses is equal to or less than a threshold.

5. The moving object of the contactless power transmission system according to claim 3, wherein
in the foreign object detection, the processor determines that the foreign object is present when a voltage change amount detected by the voltage detection unit during a predetermined time after the power conversion device is operated or after the predetermined time elapses is equal to or greater than a predetermined value.

6. The moving object of the contactless power transmission system according to claim 3, wherein
the moving-object-side unit further includes a current detection unit that is provided between the power conversion device and the capacitor to detect a current, and
in the foreign object detection,
the processor calculates an impedance based on detection results from the voltage detection unit and the current detection unit, and
the processor determines that the foreign object is present when the impedance is equal to or greater than a threshold.

7. A foreign object detection method of a contactless power transmission system, wherein
the contactless power transmission system performs contactless power transmission between a moving-object-side unit mounted on a moving object and a ground-side unit provided outside the moving object,
the moving object includes a battery and the moving-object-side unit electrically connected to the battery,
the moving-object-side unit includes a moving-object-side coil that receives or transmits power in a contactless manner from or to a ground-side coil provided in the ground-side unit, a power conversion device that is connected between the moving-object-side coil and the battery and performs power conversion between DC power and AC power, and a capacitor provided between the power conversion device and the battery, and
the foreign object detection method performed by a processor comprises:
disconnecting electrical connection between the battery and the moving-object-side unit before the contactless power transmission is performed; and
operating the power conversion device in a disconnected state in which the battery and the moving-object-side unit are disconnected, and determining whether a metal foreign object is present between the moving-object-side unit and the ground-side unit.

8. A non-transitory computer-readable storage medium storing a foreign object detection program of a contactless power transmission system for causing a computer to execute a process, wherein
wherein the contactless power transmission system performs contactless power transmission between a moving-object-side unit mounted on a moving object and a ground-side unit provided outside the moving object,
the moving object includes a battery and the moving-object-side unit electrically connected to the battery,
the moving-object-side unit includes a moving-object-side coil that receives or transmits power in a contactless manner from or to a ground-side coil provided in the ground-side unit, a power conversion device that is connected between the moving-object-side coil and the battery and performs power conversion between DC power and AC power, and a capacitor provided between the power conversion device and the battery, and
the process comprises:
disconnecting electrical connection between the battery and the moving-object-side unit before the contactless power transmission is performed; and
operating the power conversion device in a disconnected state in which the battery and the moving-object-side unit are disconnected, and determining whether a metal foreign object is present between the moving-object-side unit and the ground-side unit.
